(19) United States
(12) Patent Application Publication
(10) Pub. No.: US 2006/0012939 A1
(43) Pub. Date: Jan. 19, 2006

(54) Clamp for use in processing semiconductor workpieces

(75) Inventors: David E. Suuronen, Newburyport, MA (US); Paul Murphy, Reading, MA (US)

Correspondence Address: Mark Superko;Varian Semiconductor Equipment Associates, Inc., 35 Dory Lane, Gloucester, MA, 01930-2297, US

(73) Assignee: Varian Semiconductor Equipment Associates, Inc., Gloucester, MA (US)

(21) Appl. No.: 11/101,832

(22) Filed: Apr. 8, 2005

Related U.S. Application Data
(60) Provisional application No. 60/560,912, filed on Apr. 9, 2004.

(51) Int. Cl. H01L 21/683

(52) U.S. Cl. 361/234

(57) ABSTRACT

An apparatus is provided to improve clamping of a work piece to a support surface. The apparatus includes a support base, an insulator layer disposed on the support base, an electrode layer disposed on the insulator layer, and a clamping layer comprising aluminum oxynitride disposed on the electrode layer wherein the workpiece is clamped to the surface of the clamping layer. The apparatus provides a higher clamping force for the workpiece while reducing gas leakage and particle levels in addition to maintaining a declamping time suitable for high throughput processing. The apparatus may also include a support base, an insulator layer disposed on the support base, an electrode layer disposed on the insulator layer, and a clamping layer comprising a dielectric layer and a resilient material layer disposed on the electrode layer wherein the workpiece is clamped to the surface of the clamping layer. The apparatus and configurations of the dielectric and resilient layers further reduce backside particle generation while providing a high clamping force for the workpiece.

### RELATED APPLICATIONS

This application claims priority under 35 U.S.C. § 119(e) to U.S. Provisional Patent Application Ser. No. 60/560,912, filed Apr. 9, 2004, entitled “Electrostatic Clamp For Use In Processing Semiconductor Workpieces,” the disclosure of which is hereby incorporated by reference.

### BACKGROUND

In the fabrication of integrated circuits, a number of well-established processes involve the application of ion beams to semiconductor wafers in vacuum. These processes include, for example, ion implantation, ion beam milling, and reactive ion etching. In each instance, an ion beam is generated in a source and is directed with varying degrees of acceleration toward a target wafer. Ion implantation has become a standard technique for introducing conductivity altering impurities into semiconductor wafers. A desired impurity material is ionized in an ion source, the ions are accelerated to form an ion beam of determined energy and is directed at the surface of a wafer. Energetic ions penetrate into the bulk of the semiconductor material becoming embedded in the crystalline lattice of the semiconductor material to form a region of desired conductivity.

The semiconductor wafer must be firmly clamped in a position for ion implantation. A number of methods are known in the art to clamp a wafer. One such technique involves the application of electrostatic forces to firmly position the wafer. A dielectric layer is positioned between the semiconductor wafer and electrodes, and insulated from a support plate. Voltages of opposite polarities applied to pairs of electrodes generate electrostatic forces firmly holding a semiconductor wafer against the dielectric layer.

It has been previously known that materials, such as alumina, sapphire, silicon carbide, aluminum nitride, and diamond have been used as material for the dielectric layer. Alumina is widely used material for the dielectric layer for its cost and ready availability.

A transparent ceramic material has been disclosed in U.S. Pat. Nos. 4,481,300; 4,520,116; 4,720,362; and 5,135,814. Its optical transparency, as well as its transmissibility characteristics in the ultraviolet, visible and infrared spectrums characterizes this transparent ceramic material known as aluminum oxynitride. However, this material is used primarily for military applications for windows, radar and infrared domes to protect sensor packages on missiles and aircraft. Aluminum oxynitride was not believed to be applicable for electrostatic clamps due the difficulty in processing aluminum oxynitride powders and manufacturability of the very thin dielectric layer, in addition to unknown technical performance characteristics.

Problems associated with electrostatic clamps disclosed in U.S. Pat. No. 6,388,861 include insufficient wafer clamping force, charging current damage to devices on the wafer, difficulty in making electrical contact to the semiconductor wafer, wafer declamp time, and inadequate transfer of heat from a semiconductor wafer work piece. Furthermore, customer applications have identified leakage of cooling gas into the process chamber, particles, dielectric withstand voltage, and platen lifetime as being additional performance requirements.

### SUMMARY OF THE INVENTION

It is the general object of this present invention to provide improved methods and apparatus for clamping of a work piece to a support surface.

According to a first aspect of the invention, an apparatus comprises a support base, an insulator layer disposed on the support base, an electrode layer disposed on the insulator layer, and a clamping layer comprising aluminum oxynitride disposed on the electrode layer wherein the workpiece is clamped to the surface of the clamping layer. The apparatus provides a higher clamping force for the workpiece while reducing gas leakage and particle levels in addition to maintaining a declamping time suitable for high throughput processing.

According to another aspect of the invention, an apparatus comprises a support base, an insulator layer disposed on the support base, an electrode layer disposed on the insulator layer, and a clamping layer comprising a dielectric layer and a resilient material layer disposed on the electrode layer wherein the workpiece is clamped to the surface of the clamping layer. The apparatus and configurations of the dielectric and resilient layers further reduce backside particle generation while providing a high clamping force for the workpiece.

It is another object of this present invention to provide improved methods and apparatus for electrostatic or mechanical semiconductor wafer clamping.

A further object of this present invention is to provide an electrostatic clamping apparatus with a high withstand voltage for the use with semiconductor wafers.

An additional object of this invention is to provide an electrostatic clamping apparatus with low particle generation.

Another object of this invention is to provide an electrostatic clamping apparatus with a flat surface for zero degree implants.

It is another object of this invention is to provide an electrostatic clamping apparatus which controls the leakage of cooling gas into the ion implanter process chamber.

Yet another object of this present invention is to provide an electrostatic clamping apparatus with longer lifetime.

### BRIEF DESCRIPTION OF THE DRAWINGS

For a better understanding of the present invention together with other and further objects, advantages and capabilities thereof, reference is made to the accompanying drawings which are incorporated herein by reference:

FIGS. 1(a) and (b) illustrate cross sectional and top views respectively of an aluminum oxynitride clamp according to an embodiment of the present invention;

FIGS. 2(a) and 2(b) illustrate cross sectional and top views respectively of a clamp having a dielectric ring with a resilient center according to another embodiment of the present invention;

FIGS. 3(a) and 3(b) illustrate cross sectional and top views respectively of a clamp having a dielectric ring with a resilient center according to a further embodiment of the present invention;

FIGS. 4(a) and 4(b) illustrate cross sectional and top views respectively of a clamp having a dielectric layer and a resilient layer according to another embodiment of the present invention;

FIGS. 5(a) and 5(b) illustrate cross sectional and top views respectively of a clamp having a dielectric layer having a plurality of protrusions and resilient layers according to a further embodiment of the present invention;

FIGS. 6(a) and 6(b) illustrate cross sectional and top views respectively of a clamp having a dielectric layer having a plurality of protrusions and resilient layers according to another embodiment of the present invention;

FIGS. 7(a) and 7(b) illustrate cross sectional and top views respectively of a clamp having a dielectric layer and a resilient layer having a plurality of gas channels according to another embodiment of the present invention; and

FIGS. 8(a) and 8(b) illustrate cross sectional and top views respectively of a clamp having a dielectric layer including a plurality of protrusions according to another embodiment of the present invention.

### DESCRIPTION OF THE INVENTION

According to the present invention, these objects and advantages are achieved in the apparatus for electrostatic clamping of workpieces as indicated in the following figures.

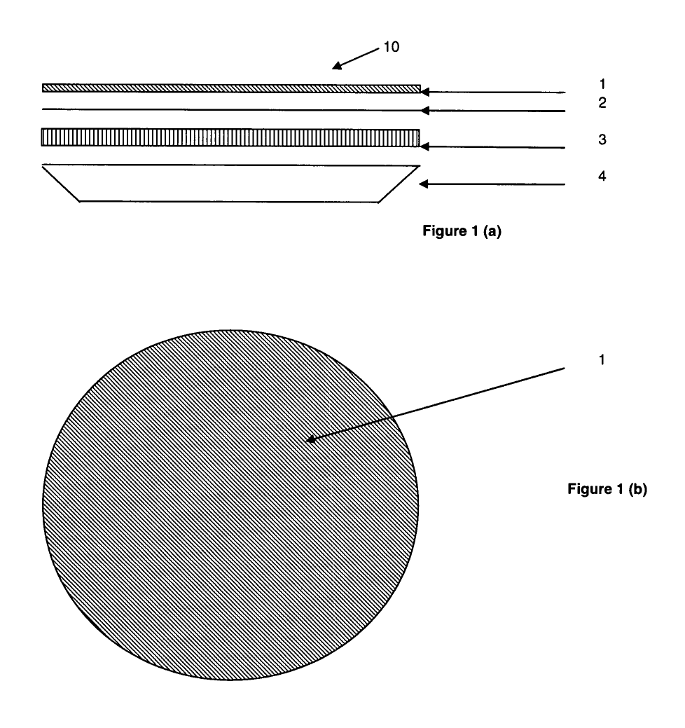

One embodiment of a clamp 10 is shown in FIGS. 1(a) and 11(b) wherein the dielectric layer 1 may be comprised of aluminum oxynitride and the insulator layer 3 may be comprised of alumina. The electrode 2 may be made of metal and a support base 4 of aluminum. Cooling gas is distributed via conventional cooling gas holes in the electrostatic clamp surface. A workpiece may be electrostatically or mechanically clamped to the clamping surface using known electrostatic or mechanical clamping techniques. An electrostatic clamp 10 of such a design has been fabricated and tested in an ion implanter. Test results indicate that the aluminum oxynitride can yield higher clamping force, lower gas leakage, lower particle levels and longer lifetime due to the material's durability, along with a declamping time compatible with high throughput ion implantation applications.

An additional embodiment includes an insulator layer 3 comprised of aluminum oxynitride or like material such as but not limited to alumina, sapphire, silicon carbide, aluminum nitride, diamond or material with properties similar to aluminum oxynitride.

Furthermore, another embodiment consists of a dielectric layer 1 of alumina, sapphire, silicon carbide, aluminum nitride, diamond or material with properties similar to aluminum oxynitride. Aluminum oxynitride provides optimal benefits in terms of both cost and functionality as compared to the other materials.

An additional embodiment includes both the insulator and dielectric comprised of aluminum oxynitride.

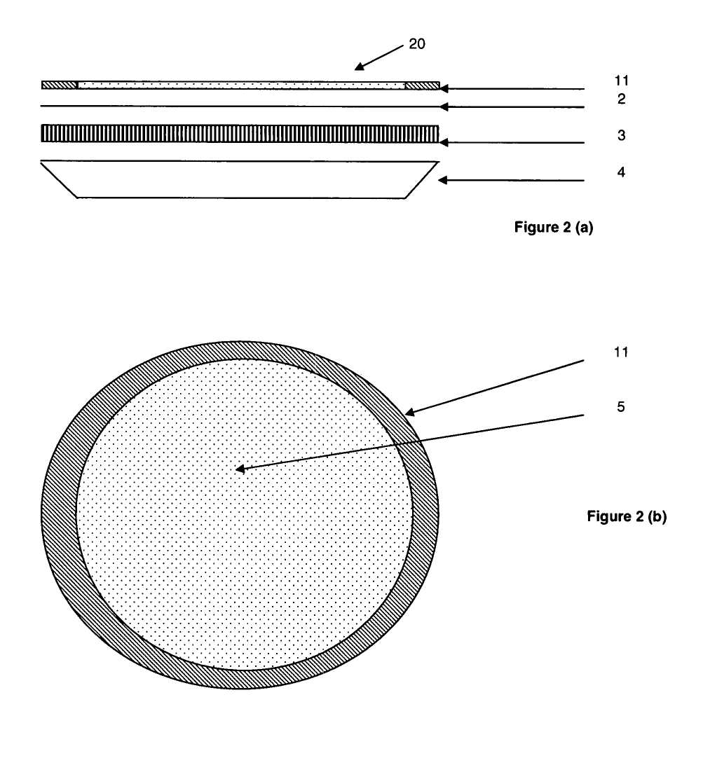

Another embodiment of a clamp 20 is shown in FIGS. 2(a) and 2(b) where the dielectric layer 11 is comprised of center section or resilient layer 5 of resilient material such as but not limited to silicone rubber surrounded by an annular or dielectric ring 11 comprised of aluminum oxynitride, alumina, sapphire, silicon carbide, aluminum nitride, diamond or any such a material with properties similar to aluminum oxynitride. The resilient layer 5 can have a filler material such as but not limited to silicon dioxide, silicon nitride, titanium dioxide, aluminum oxide, iron oxide or carbon black for enhancing heat transfer between semiconductor wafer and the electrostatic clamp 20. The annular ring 11 affords of an adequate width so as not to affect the testing for backside particles and provides an effective seal for cooling gas leakage into the process chamber of an ion implanter or such similar devices. The resilient material layer 5 centrally located affords a reduction in the generation of backside particle generation.

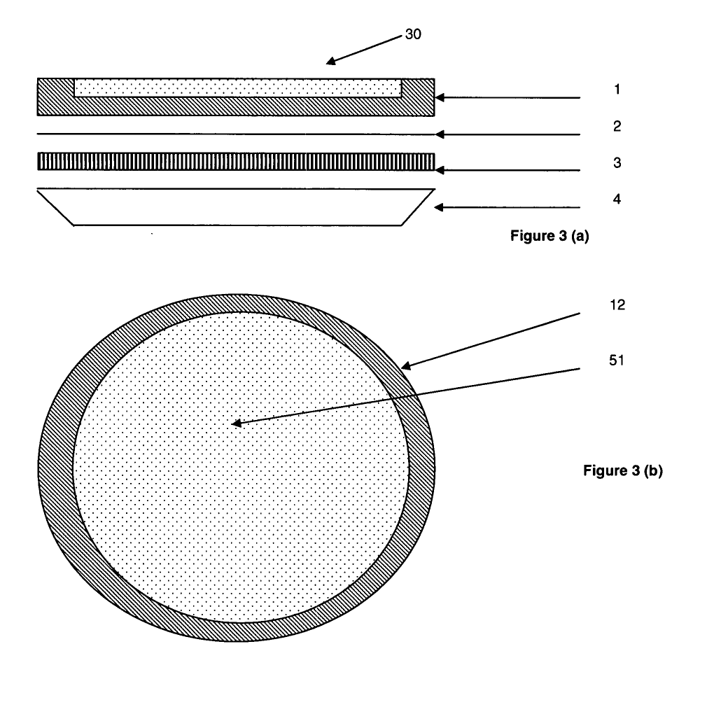

An alternate embodiment of a clamp 30 shown in FIGS. 3(a) and 3(b) comprises a dielectric layer 1 wherein there is a recessed cavity to capture a resilient layer 51 such as but not limited to silicone rubber surrounded by an annular or dielectric ring 12 comprised of alumina, sapphire, silicon carbide, aluminum nitride, diamond or any such a material with properties similar to aluminum oxynitride. The resilient layer 51 can have a filler material such as but not limited to silicon dioxide, silicon nitride, titanium dioxide, aluminum oxide, iron oxide or carbon black for enhancing heat transfer between semiconductor wafer and electrostatic clamp 30. The annular ring 12 affords an adequate width so as not to affect the testing for backside particles and provides an effective seal for cooling gas leakage into the process chamber of an ion implanter or such similar devices. The resilient material 51 centrally located provides means to reduce the generation of particles. The structure provides a high withstand voltage capability due the aluminum oxynitride dielectric.

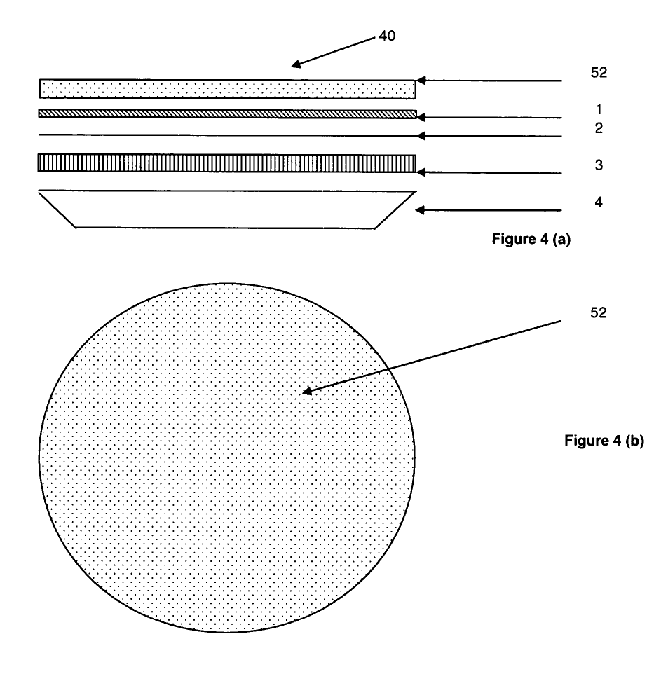

A further embodiment of a clamp 40 shown in FIGS. 4(a) and 4(b), as compared to the embodiment shown in FIGS. 2(a) and 2(b), comprises a resilient layer 52 with a filler material such as but not limited to silicon dioxide, silicon nitride, titanium dioxide, aluminum oxide, iron oxide or carbon black to enhance heat transfer between semiconductor wafer and eclamp. This is attached to the dielectric layer 1 comprised of aluminum oxynitride, alumina, sapphire, silicon carbide, aluminum nitride, diamond or any such a material with properties similar to aluminum oxynitride. The resilient material layer 52 provides means to reduce the generation of particles. The dielectric layer 1 of aluminum oxynitride provides a high withstand voltage capability.

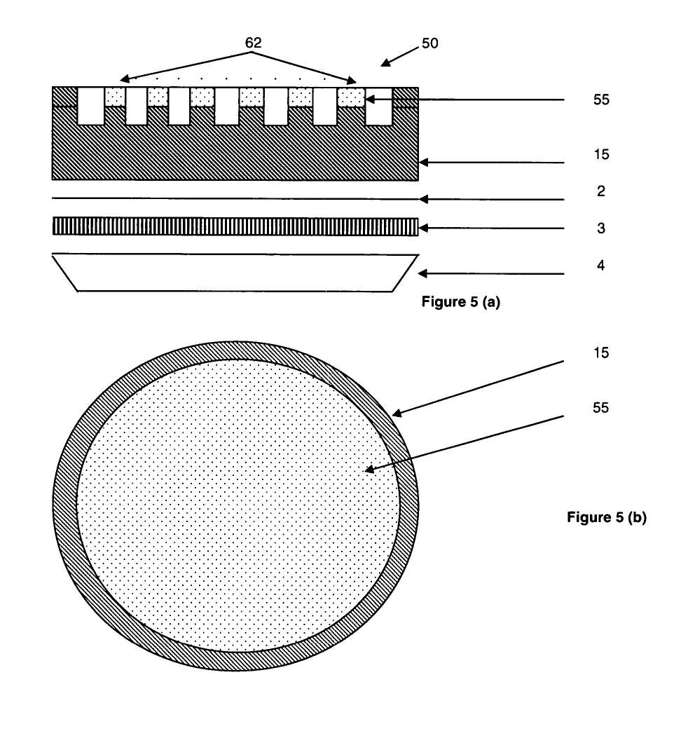

Shown in FIGS. 5(a) and 5(b) is an embodiment of a clamp 50 wherein the dielectric layer 15 is comprised of aluminum oxynitride, alumina, sapphire, silicon carbide, aluminum nitride, diamond or any such a material with properties similar to aluminum oxynitride and exhibits vertical protrusions 62 on top of which is a resilient layer 55 of resilient material such as but not limited to silicone rubber. The resilient layer 55 can have a filler material such as but not limited to silicon dioxide, silicon nitride, titanium dioxide, aluminum oxide, iron oxide or carbon black for enhancing heat transfer between semiconductor wafer and electrostatic clamp 50. The geometric dimensions and multiple placement of the protrusions 62 contribute to clamping force; distribution of cooling gas and heat transfer between the semiconductor wafer and the clamp 50; voltage withstand characteristics; particle generation and mechanical support of the work piece.

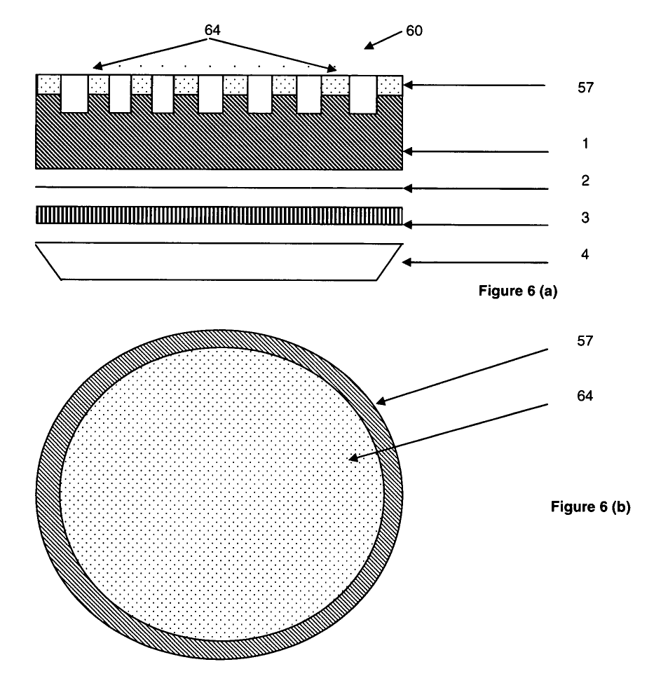

The embodiment of FIGS. 6(a) and 6(b) of a clamp 60 includes a dielectric layer 1 comprised of aluminum oxynitride, alumina, sapphire, silicon carbide, aluminum nitride, diamond or any such a material with properties similar to aluminum oxynitride and exhibits vertical protrusions 64 on top of which is a resilient layer 57 of resilient material such as but not limited to silicone rubber. The resilient layer 57 can have a filler material such as but not limited to silicon dioxide, silicon nitride, titanium dioxide, aluminum oxide, iron oxide or carbon black for enhancing heat transfer between semiconductor wafer and electrostatic clamp 64. The width, height, multiple placement and geometry of the protrusions 64 are dependent upon the requirements for clamping force; distribution of cooling gas, heat transfer between semiconductor wafer and eclamp; voltage withstand characteristics; particle generation; and mechanical support of the work piece. In addition, the annular ring 57 comprised of resilient material such as but not limited to silicone rubber wherein the resilient material may or may not be enhanced with additives, as described previously, for transfer of heat energy between semiconductor wafer and the clamp 60. The annular ring 57 is of adequate width depending upon the requirements for backside particles and effective sealing against leaking cooling gas.

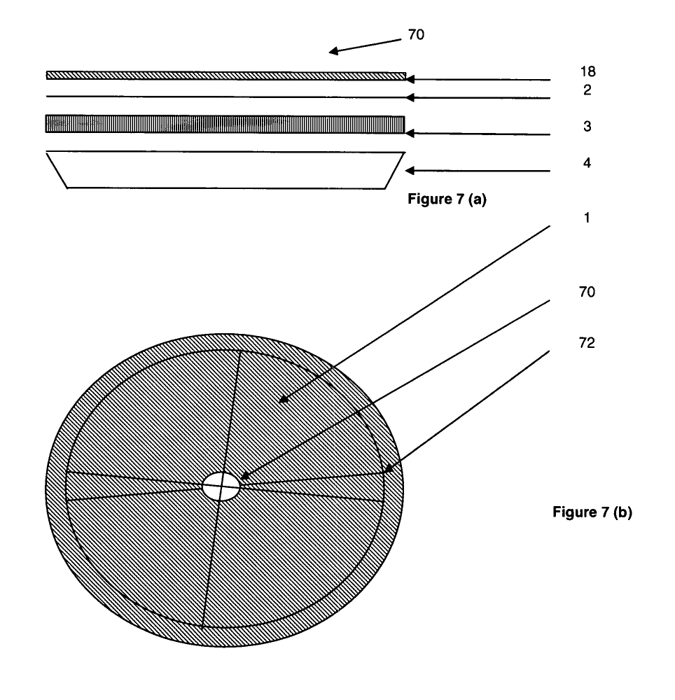

Another embodiment of a clamp 70 is illustrated in FIGS. 7(a) and 7(b) employs a dielectric layer 18 whose material is comprised of aluminum oxynitride, alumina, sapphire, silicon carbide, aluminum nitride, diamond or any such a material with properties similar to aluminum oxynitride; and with an engineered cooling gas distribution system including a center gas supply 70 having gas channels 72 are not necessarily of consistent uniform cross-section, but may include, as required, transitional regions of non-uniform cross-section in order to facilitate the transfer of heat energy between semiconductor wafer and the clamp 70. The depth, width, location and number of the gas channels 72 are dependent upon the type of cooling gas and the requirements to adequately cool the wafer during the implant process.

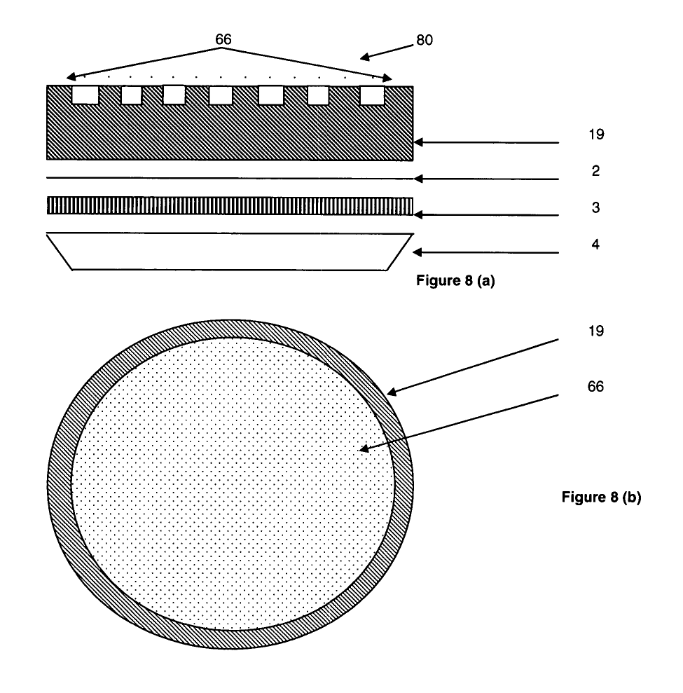

The embodiment of a clamp 80 in FIGS. 8(a) and 8(b) includes a dielectric layer 19 comprised of aluminum oxynitride, alumina, sapphire, silicon carbide, aluminum nitride, diamond or any such a material with properties similar to aluminum oxynitride and exhibits vertical protrusions 66 of resilient material such as but not limited to silicone rubber in dielectric layer 19, although the protrusions could be on top of dielectric layer 19. The width, height, placement and geometry of the protrusions 66 are dependent upon the requirements for clamping force; distribution of cooling gas, heat transfer between semiconductor wafer and clamp 80; voltage withstand characteristics; particle generation; and mechanical support of the work piece.

Many modifications and variations may become apparent in light of the above teachings. Many additional changes in the details, materials, and arrangement of parts, herein described and illustrated, can be made by those skilled in the art. Accordingly, it will be understood that the present invention is not to be limited to the embodiments disclosed herein, can include practices otherwise than specifically described, and are to be interpreted as broadly as allowed under the law.

1. (canceled)

2. (canceled)

3. (canceled)

4. (canceled)

5. (canceled)

6. (canceled)

7. (canceled)

8. (canceled)

9. (canceled)

10. An apparatus for clamping a semiconductor workpiece, comprising:
a support base;
an insulator layer disposed on the support base;
an electrode layer disposed on the insulator layer;
a clamping layer comprising a dielectric layer and a resilient material layer disposed on the electrode layer, wherein the workpiece is clamped to the surface of the clamping layer.

11. An apparatus according to claim 10, wherein the workpiece is electrostatically clamped to the workpiece.

12. An apparatus according to claim 10, wherein the workpiece is mechanically clamped to the workpiece.

13. An apparatus according to claim 10, wherein the support base comprises aluminum.

14. An apparatus according to claim 10, wherein the insulator layer comprises alumina, sapphire, silicon carbide, aluminum nitride, or diamond.

15. An apparatus according to claim 10, wherein the electrode layer comprises metal.

16. An apparatus according to claim 10, wherein the workpiece comprises a semiconductor wafer.

17. (canceled)

18. An apparatus according to claim 10, wherein the dielectric material comprises alumina, sapphire, silicon carbide, aluminum nitride, or diamond.

19. An apparatus according to claim 10, wherein the resilient material comprises silicone rubber and a filler material of silicon dioxide, silicon nitride, titanium dioxide, aluminum oxide, iron oxide or carbon black.

20. An apparatus according to claim 10, wherein the clamping layer comprises the dielectric layer having a recessed cavity of a predetermined depth formed in the center portion thereof and the resilient martial layer is formed in the recessed cavity.

21. An apparatus according to claim 10, wherein the clamping layer comprises the dielectric layer and the resilient material layer disposed on the surface of the dielectric layer.

22. An apparatus according to claim 10, wherein the dielectric layer comprises a plurality of protrusions extending from the surface thereof and the resilient material layer formed on predetermined ones of the protrusions to extend from the surface to a predetermined height.

23. An apparatus according to claim 22, wherein the resilient material is formed on each of the protrusions.

24. An apparatus according to claim 22, wherein the resilient material is formed on internal protrusions of the clamping layer excluding an outer annular ring thereof wherein the dielectric material on the outer annular ring extends to approximately the same height as the height of the resilient material on the internal protrusions.
